(19) United States
(12) Patent Application Publication
(10) Pub. No.: US 2024/0049513 A1
(43) Pub. Date: Feb. 8, 2024

(54) DISPLAY PANEL, METHOD FOR MANUFACTURING SAME, AND DISPLAY DEVICE

(71) Applicant: Shenzhen China Star Optoelectronics Semiconductor Display Technology Co., Ltd., Shenzhen, Guangdong (CN)

(72) Inventor: Wenjie LI, Shenzhen (CN)

(21) Appl. No.: 17/760,855

(22) PCT Filed: Mar. 2, 2022
(86) PCT No.: PCT/CN2022/078749

§ 371 Date: Mar. 16, 2022

(30) Foreign Application Priority Data
Feb. 18, 2022 (CN) 202210148991.2

(51) Int. Cl. H10K 59/122; H10K 59/12; H10K 59/80

(52) U.S. Cl. CPC H10K 59/122; H10K 59/1201; H10K 59/80516

(57) ABSTRACT

A display panel, a method for manufacturing the same, and a display device are provided. The display panel includes a plurality of anode electrodes, a first pixel definition layer provided with a plurality of first pixel openings, and a second pixel definition layer. At least two of the anode electrodes are disposed in one of the first pixel openings. Each of the first pixel openings has at least two light-emitting pixels with a same light-emitting color, and each of the light-emitting pixels corresponds to one of the anode electrodes. The second pixel definition layer is disposed at least between two adjacent anode electrodes in each of the first pixel openings. A height of the first pixel definition layer is greater than a height of the second pixel definition layer.

### FIELD OF INVENTION

The present disclosure relates to the technical field of display, and particularly to a display panel, a method for manufacturing the same, and a display device.

### BACKGROUND

In recent years, inkjet printing has advantages of high material utilization rate, low equipment price, and the like. Inkjet printing is the best way to product large-sized and low-cost organic light-emitting diodes (OLEDs). Limited by a landing accuracy of printing ink droplets and an interval between printing nozzles, it is difficult to print with high pixel density. Considering a small length of sub-pixels, a small interval between the printing nozzles, and a landing deviation of the printing ink droplets, the actual number of the printing nozzles available is very small. If one of the printing nozzles is blocked and cannot print ink, an amount of a printing ink in one corresponding sub-pixel will be too small, which will reduce a printing quality and reduce a display effect.

Therefore, there is an urgent need for a display panel, a method for manufacturing the same, and a display device to solve the aforementioned technical problem.

### SUMMARY OF DISCLOSURE

The present disclosure provides a display panel, a method for manufacturing the same, and a display device to solve a technical problem that a printing quality is reduced due to clogging of some printing nozzles.

In order to solve the aforementioned technical problem, the present disclosure provides the following technical solutions.

The present disclosure provides a display panel comprising:
a substrate;
an anode layer disposed on the substrate and comprising a plurality of anode electrodes that are separately arranged;
a first pixel definition layer disposed on the substrate and provided with a plurality of first pixel openings, wherein in a top view direction of the display panel, at least two of the anode electrodes are disposed in one of the first pixel openings; and
a second pixel definition layer disposed on the substrate and disposed at least between two adjacent anode electrodes in each of the first pixel openings;
wherein light-emitting pixels in one of the first pixel openings have a same light-emitting color, and a distance between a surface of the first pixel definition layer away from the substrate and a surface of the substrate close to the first pixel definition layer is greater than a distance between a surface of the second pixel definition layer away from the substrate and a surface of the substrate close to the second pixel definition layer.

In an embodiment, the second pixel definition layer is disposed on a periphery of each of the anode electrodes. The second pixel definition layer is provided with a plurality of second pixel openings. One of the second pixel openings corresponds to one of the anode electrodes. The first pixel definition layer is disposed on the surface of the second pixel definition layer away from the substrate. In the top view direction of the display panel, at least two of the second pixel openings are located in one of the first pixel openings.

In an embodiment, in the top view direction of the display panel, in each of the first pixel openings, a column of the anode electrodes arranged in a first direction, the light-emitting pixels in a same column of the first pixel openings in the first direction have a same light-emitting color. The light-emitting pixels in two adjacent columns of the first pixel openings in a second direction have different light-emitting colors. The first direction is perpendicular to the second direction.

In an embodiment, the anode layer further comprises a plurality of auxiliary electrodes disposed in a same layer as the anode electrodes and insulated from the anode electrodes. In the first direction, each of the auxiliary electrodes is disposed between two adjacent first pixel openings.

In an embodiment, two adjacent first pixel openings in the first direction have different numbers of the anode electrodes, and two adjacent first pixel openings in the second direction are not flush with each other.

In an embodiment, in a direction from an edge of the display panel to a center of the display panel, a number density of the auxiliary electrodes gradually increases.

In an embodiment, the display panel further comprises a plurality of light-emitting layers disposed on the anode electrodes, and a cathode layer disposed on the light-emitting layers. The cathode layer is electrically connected to the auxiliary electrodes through via holes.

In an embodiment, a thickness of the second pixel definition layer is greater than or equal to a thickness of the anode electrodes.

In an embodiment, the second pixel definition layer is in contact with surfaces of the anode electrodes away from the substrate.

In an embodiment, a surface hydrophobicity of the first pixel definition layer is greater than a surface hydrophobicity of the second pixel definition layer.

The present disclosure further provides a method for manufacturing a display panel. The method comprises:
providing a substrate;
forming a plurality of anode electrodes separately disposed on the substrate;
forming a second pixel definition material layer on the anode electrodes;
patterning the second pixel definition material layer to form a second pixel definition layer exposing the anode electrodes;
forming a first pixel definition material layer on the substrate;
patterning the first pixel definition material layer to form a first pixel definition layer having a plurality of first pixel openings, wherein at least two of the anode electrodes are disposed in one of the first pixel openings, the second pixel definition layer is disposed at least between two adjacent anode electrodes in each of the first pixel openings, and a distance between a surface of the first pixel definition layer away from the substrate and a surface of the substrate close to the first pixel definition layer is greater than a distance between a surface of the second pixel definition layer away from the substrate and a surface of the substrate close to the second pixel definition layer; and
forming a light-emitting layer in each of the first pixel openings by inkjet printing a same color ink.

In an embodiment, the patterning the second pixel definition material layer to form the second pixel definition layer exposing the anode electrodes comprises: patterning the second pixel definition material layer to form the second pixel definition layer having a plurality of second pixel openings. One of the second pixel openings exposes one of the anode electrodes. The forming the first pixel definition material layer on the substrate comprises: forming the first pixel definition material layer on the second pixel definition layer.

In an embodiment,
the forming the anode electrodes separately disposed on the substrate comprises:
forming the anode electrodes and a plurality of auxiliary electrodes on the substrate, wherein the anode electrodes are separately arranged, and each of the auxiliary electrodes is disposed between two adjacent anode electrodes;
the patterning the second pixel definition material layer to form the second pixel definition layer exposing the anode electrodes comprises:
patterning the second pixel definition material layer to form the second pixel definition layer exposing the anode electrodes and the auxiliary electrodes;
the patterning the first pixel definition material layer to form the first pixel definition layer having the first pixel openings comprises:
patterning the first pixel definition material layer to form a first pixel definition layer having the first pixel openings and a plurality of first via holes, wherein the first via holes expose the auxiliary electrodes; and
the forming the light-emitting layer in each of the first pixel openings by inkjet printing the same color ink comprises:
forming the light-emitting layer in each of the first pixel openings by inkjet printing the same color ink; and
forming a cathode layer on the light-emitting layers and the auxiliary electrodes.

The present disclosure further provides a display device comprising a display panel and a device body. The display panel and the device body are combined into one body. The display panel comprises:
a substrate;
an anode layer disposed on the substrate and comprising a plurality of anode electrodes that are separately arranged;
a first pixel definition layer disposed on the substrate and provided with a plurality of first pixel openings, wherein in a top view direction of the display panel, at least two of the anode electrodes are disposed in one of the first pixel openings; and
a second pixel definition layer disposed on the substrate and disposed at least between two adjacent anode electrodes in each of the first pixel openings;
wherein light-emitting pixels in one of the first pixel openings have a same light-emitting color, and a distance between a surface of the first pixel definition layer away from the substrate and a surface of the substrate close to the first pixel definition layer is greater than a distance between a surface of the second pixel definition layer away from the substrate and a surface of the substrate close to the second pixel definition layer.

In an embodiment, the second pixel definition layer is disposed on a periphery of each of the anode electrodes. The second pixel definition layer is provided with a plurality of second pixel openings. One of the second pixel openings corresponds to one of the anode electrodes. The first pixel definition layer is disposed on the surface of the second pixel definition layer away from the substrate. In the top view direction of the display panel, at least two of the second pixel openings are located in one of the first pixel openings.

In an embodiment, in the top view direction of the display panel, in each of the first pixel openings, a column of the anode electrodes arranged in a first direction, the light-emitting pixels in a same column of the first pixel openings in the first direction have a same light-emitting color. The light-emitting pixels in two adjacent columns of the first pixel openings in a second direction have different light-emitting colors. The first direction is perpendicular to the second direction.

In an embodiment, the anode layer further comprises a plurality of auxiliary electrodes disposed in a same layer as the anode electrodes and insulated from the anode electrodes. In the first direction, each of the auxiliary electrodes is disposed between two adjacent first pixel openings.

In an embodiment, two adjacent first pixel openings in the first direction have different numbers of the anode electrodes, and two adjacent first pixel openings in the second direction are not flush with each other.

In an embodiment, a thickness of the second pixel definition layer is greater than or equal to a thickness of the anode electrodes.

In an embodiment, a surface hydrophobicity of the first pixel definition layer is greater than a surface hydrophobicity of the second pixel definition layer.

In the present disclosure, the second pixel definition layer is configured to insulate two adjacent anode electrodes, so that light emission of the two adjacent light-emitting pixels can be independently controlled. An ink is printed in one first pixel opening, and an amount of the ink corresponds to at least two light-emitting pixels of a same color. Even if one printing nozzle is blocked, the amount of the ink corresponding to at least two light-emitting pixels is evenly distributed. This can reduce a relative error of an ink amount caused by a reduction of an ejected ink amount, thereby improving a printing quality and improving a display effect.

### BRIEF DESCRIPTION OF DRAWINGS

FIG. 1 is a schematic top view of a first structure of a display panel according to an embodiment of the present disclosure.

FIG. 2 is an enlarged view of a region B of FIG. 1.

FIG. 3 a first schematic cross-sectional view of FIG. 1 along a line A1-A2.

FIG. 4 a second schematic cross-sectional view of FIG. 1 along the line A1-A2.

FIG. 5 a third schematic cross-sectional view of FIG. 1 along the line A1-A2.

FIG. 6 is a schematic top view of a second structure of a display panel according to an embodiment of the present disclosure.

FIG. 7 is a schematic flowchart of a method for manufacturing a display panel according to an embodiment of the present disclosure.

FIG. 8A to 8D are first schematic flowcharts of a method for manufacturing a display panel according to an embodiment of the present disclosure.

FIG. 9 is a second schematic flowchart of a method for manufacturing a display panel according to an embodiment of the present disclosure.

FIG. 10 is a schematic structural diagram of a display device according to an embodiment of the present disclosure.

### DETAILED DESCRIPTION

The present disclosure provides a display panel, a method for manufacturing the same, and a display device. In order to make purposes, technical solutions, and effects of the present invention clearer and more definite, the present invention will be further described in detail below with reference to accompanying drawings and embodiments. It should be understood that specific embodiments described herein are only used to explain the present invention, not used to limit the present invention.

The present disclosure provides a display panel, a method for manufacturing the same, and a display device, which will be described in detail below. It should be noted that a description order of the following embodiments is not intended to limit a preferred order of the embodiments.

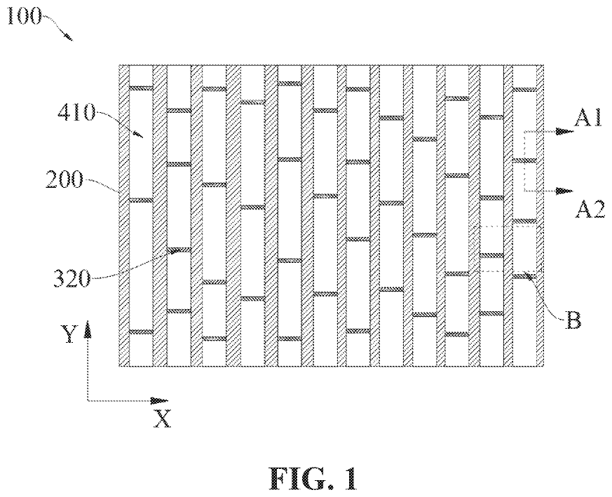

Please refer to FIG. 1 to FIG. 6, the present disclosure provides a display panel 100 comprising:
a substrate 200;
an anode layer 300 disposed on the substrate 200 and comprising a plurality of anode electrodes 310 that are separately arranged;
a first pixel definition layer 400 disposed on the substrate 200 and provided with a plurality of first pixel openings 410, wherein in a top view direction of the display panel 100, at least two of the anode electrodes 310 are disposed in one of the first pixel openings 410; and
a second pixel definition layer 500 disposed on the substrate 200 and disposed at least between two adjacent anode electrodes 310 in each of the first pixel openings 410;
wherein light-emitting pixels in one of the first pixel openings 410 have a same light-emitting color, and a distance between a surface of the first pixel definition layer 400 away from the substrate 200 and a surface of the substrate 200 close to the first pixel definition layer 400 is greater than a distance between a surface of the second pixel definition layer 500 away from the substrate 200 and a surface of the substrate 200 close to the second pixel definition layer 500.

In the present disclosure, the second pixel definition layer is configured to insulate two adjacent anode electrodes, so that light emission of the two adjacent light-emitting pixels can be independently controlled. An ink is printed in one first pixel opening, and an amount of the ink corresponds to at least two light-emitting pixels of a same color. Even if one printing nozzle is blocked, the amount of the ink corresponding to at least two light-emitting pixels is evenly distributed. This can reduce a relative error of an ink amount caused by a reduction of an ejected ink amount, thereby improving a printing quality and improving a display effect.

Technical solutions of the present disclosure will now be described with reference to specific embodiments.

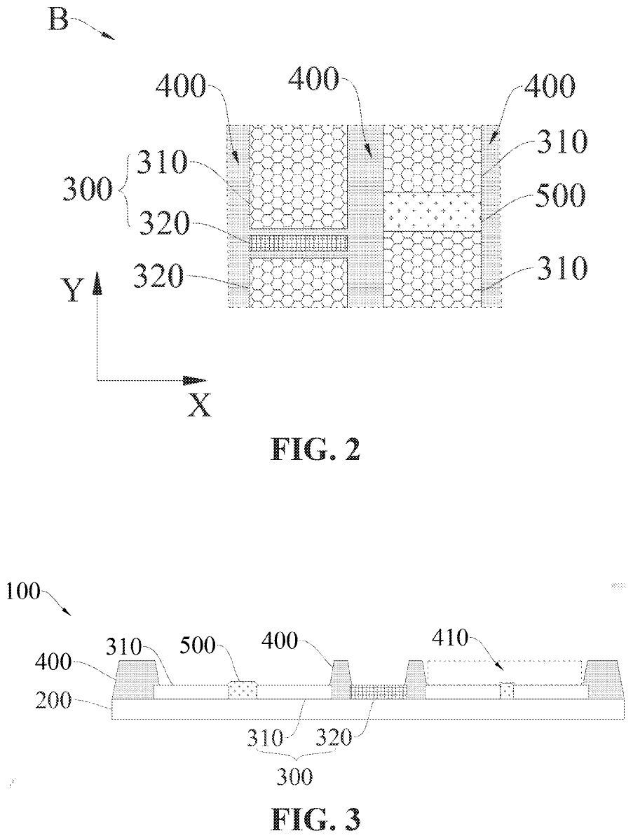

In this embodiment, please refer to FIG. 1, FIG. 2, and FIG. 3, the display panel 100 includes a substrate 200, and an anode layer 300, a first pixel definition layer 400, and a second pixel definition layer 500 that are disposed on the substrate 200.

In some embodiments, please refer to FIG. 1, FIG. 2, and FIG. 3, the anode layer 300 comprises a plurality of anode electrodes 310 that are separately arranged. The first pixel definition layer 400 is provided with a plurality of first pixel openings 410. In a top view direction of the display panel 100, at least two of the anode electrodes 310 are disposed in one of the first pixel openings 410. The second pixel definition layer 500 is disposed at least between two adjacent anode electrodes 310 in each of the first pixel openings 410. Light-emitting pixels in one of the first pixel openings 410 have a same light-emitting color. A distance between a surface of the first pixel definition layer 400 away from the substrate 200 and a surface of the substrate 200 close to the first pixel definition layer 400 is greater than a distance between a surface of the second pixel definition layer 500 away from the substrate 200 and a surface of the substrate 200 close to the second pixel definition layer 500.

In a process of manufacturing the display panel 100, the distance between the surface of the first pixel definition layer 400 away from the substrate 200 and the surface of the substrate 200 close to the first pixel definition layer 400 is greater than the distance between the surface of the second pixel definition layer 500 away from the substrate 200 and the surface of the substrate 200 close to the second pixel definition layer 500. The first pixel definition layer 400 is configured to restrict a flow of a printing ink 610. The second pixel definition layer 500 is at least configured to insulate two adjacent anode electrodes 310 in one first pixel opening 410. The first pixel definition layer 400 or the second pixel definition layer 500 may be configured to insulate two adjacent anode electrodes 310 in two adjacent first pixel openings 410 according to different patterning processes.

The light-emitting pixels in one of the first pixel openings 410 have a same light-emitting color, so an ink 610 is printed in one first pixel opening 410, and an amount of the ink 610 corresponds to at least two light-emitting pixels of a same color. Even if one printing nozzle is blocked, since the second pixel definition layer 500 does not block leveling of the ink 610, the amount of the ink 610 corresponding to at least two light-emitting pixels is evenly distributed. This can reduce a relative error of the amount of the ink 610 caused by a reduction of an ejected ink amount, thereby improving a printing quality and improving a display effect.

In some embodiments, please refer to FIG. 1, FIG. 2, and FIG. 3, there are at least two anode electrodes 310 in one of the first pixel openings 410. That is, one of the first pixel openings 410 accommodates at least two light-emitting pixels. The second pixel definition layer 500 may only be disposed between two adjacent anode electrodes 310 in each of the first pixel openings 410, so as to insulate the two adjacent anode electrodes 310, so that the two adjacent light-emitting pixels can be independently controlled to emit light.

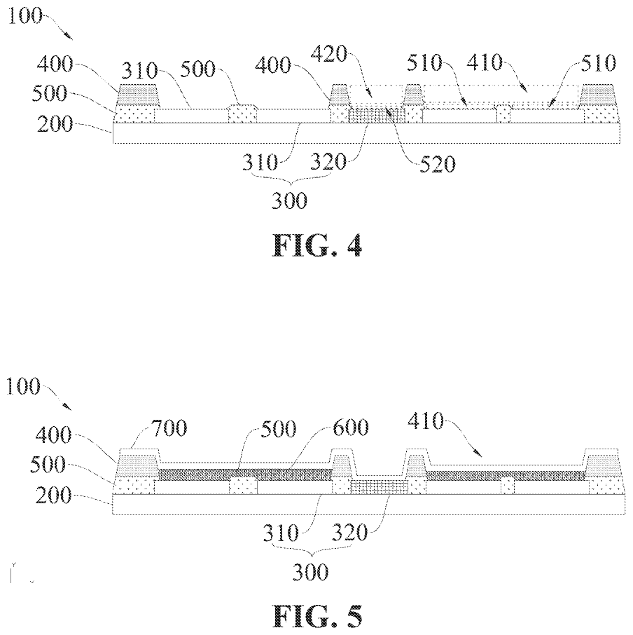

In some embodiments, please refer to FIG. 1, FIG. 2, and FIG. 4, the second pixel definition layer 500 is disposed on a periphery of each of the anode electrodes 310. The second pixel definition layer 500 is provided with a plurality of second pixel openings 510. One of the second pixel openings 510 corresponds to one of the anode electrodes 310. The first pixel definition layer 400 is disposed on the surface of the second pixel definition layer 500 away from the substrate 200. In the top view direction of the display panel 100, at least two of the second pixel openings 510 are located in one of the first pixel openings 410.

Please refer to FIG. 1, FIG. 2, and FIG. 4, the second pixel definition layer 500 is located between any two adjacent anode electrodes 310, so that any two adjacent anode electrodes 310 are insulated and can independently control light emission. The first pixel definition layer 400 is disposed on the surface of the second pixel definition layer 500 away from the substrate 200. One of the second pixel openings 510 corresponds to one of the light-emitting pixels. During fabrication, the second pixel definition layer 500 is first patterned to form only the second pixel openings 510 corresponding to the anode electrodes 310, which saves a material and is beneficial to planarization of a film layer.

In some embodiments, please refer to FIG. 1, FIG. 2, and FIG. 3, in the top view direction of the display panel 100, in each of the first pixel openings 410, a column of the anode electrodes 310 arranged in a first direction, the light-emitting pixels in a same column of the first pixel openings 410 in the first direction have a same light-emitting color. The light-emitting pixels in two adjacent columns of the first pixel openings 410 in a second direction have different light-emitting colors. The first direction is perpendicular to the second direction.

The first direction is parallel to a Y axis. The second direction is parallel to an X axis. The first direction is a column direction. The second direction is a row direction. One of the first pixel openings 410 includes only one column of the anode electrodes 310. The light-emitting pixels corresponding to the anode electrodes 310 in the same column have the same light-emitting color, which may be any one of red, green, and blue.

In some embodiments, for a top emission display panel 100, a cathode layer 70 is generally made of a metal film with high activity, such as an Mg/Ag translucent film. When a transparent cathode film has a small thickness, the transparent cathode film has a high impedance and a low conductivity. Electrode input terminals with different distances produce different voltage drops.

The anode layer further comprises a plurality of auxiliary electrodes 320 disposed in a same layer as the anode electrodes 310 and insulated from the anode electrodes 310. In the first direction, each of the auxiliary electrodes 320 is disposed between two adjacent first pixel openings 410.

The auxiliary electrodes 320 can adjust voltage drops, so that each region of the display panel 100 has a same voltage drop, thereby improving the display effect.

In some embodiments, please refer to FIG. 1, two adjacent first pixel openings 410 in the first direction have different numbers of the anode electrodes 310, and two adjacent first pixel openings 410 in the second direction are not flush with each other. In FIG. 1, the number of the anode electrodes 310 in one of the first pixel openings 410 may be represented by a length of the first pixel opening 410 in the first direction.

For example, an i-th first pixel opening 410 is adjacent to an i+1-th first pixel opening 410. In the first direction, one end of the first pixel opening 410 close to a first side of the display panel 100 is a first end, and one end of the first pixel opening 410 close to a second side of the display panel 100 is a second end. Taking a geometric center of the display panel 100 as an origin of an XY coordinate system, Y-axis coordinate values of a first end of the i-th first pixel opening 410 and a first end of the i+1-th first pixel opening 410 are different, and Y-axis coordinate values of a second end of the i-th first pixel opening 410 and a second end of the i+1-th first pixel opening 410 are different.

On the one hand, the auxiliary electrodes 320 may be disposed at different positions to adjust voltage drops in different regions. On the other hand, the auxiliary electrodes 320 do not emit light. The anode electrodes 310 are arranged in an array, and corresponding light-emitting pixels are arranged in an array. The auxiliary electrodes 320 are arranged not parallel to the Y axis, which can prevent non-light-emitting areas from affecting the display effect.

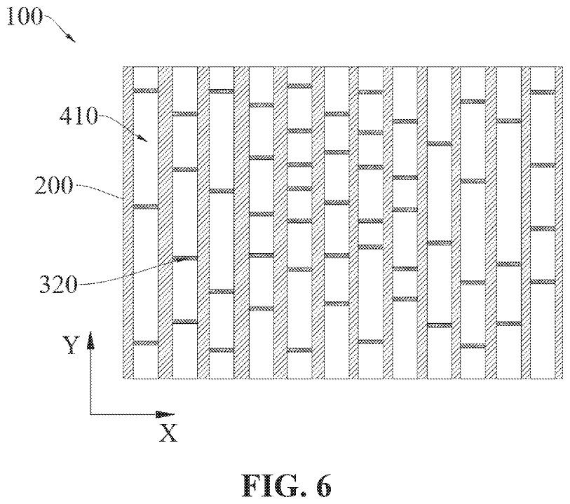

In some embodiments, please refer to FIG. 6, in a direction from an edge of the display panel 100 to a center of the display panel 100, a number density of the auxiliary electrodes 320 gradually increases.

The display panel 100 further includes a plurality of driver chips. For a large-sized display panel 100, the driver chips are disposed around the display panel 100, so that a brightness of the edge of the display panel 100 is greater than a brightness of the center of the display panel 100. Therefore, an overall uniformity of images is poor, which affects the display effect. In the direction from the edge of the display panel 100 to the center of the display panel 100, the number density of the auxiliary electrodes 320 gradually increases, thereby improving a voltage drop of a part of a cathode electrode in the center of the display panel 100, and balancing an overall voltage drop of the display panel 100, and improving the display effect.

In some embodiments, please refer to FIG. 5, the display panel 100 further comprises a plurality of light-emitting layers 600 disposed on the anode electrodes 310, and a cathode layer 700 disposed on the light-emitting layers 600. The cathode layer 700 is electrically connected to the auxiliary electrodes 320 through via holes.

The cathode layer 700 is electrically connected to the auxiliary electrodes 320 to reduce a voltage drop of the cathode electrode, thereby balancing the overall voltage drop of the display panel 100 and improving the display effect.

In some embodiments, film layers between the cathode layer 700 and the auxiliary electrodes 320 are patterned to form the via holes between the cathode layer 700 and the auxiliary electrodes 320.

In some embodiments, please refer to FIG. 3, only the first pixel definition layer 400 is disposed between the cathode layer 700 and the auxiliary electrodes 320. The first pixel definition layer 400 is provided with a plurality of first via holes 420. The first via holes 420 correspond to the auxiliary electrodes 320. In a manufacturing process, the auxiliary electrodes 320 are exposed, and the cathode layer 700 is electrically connected to the auxiliary electrodes 320 through the first via holes 420.

In some embodiments, please refer to FIG. 4 and FIG. 5, the second pixel definition layer 500 and the first pixel definition layer 400 are disposed between the cathode layer 700 and the auxiliary electrodes 320. The pixel definition layer is provided with a plurality of first via holes 420. The second pixel definition layer 500 is provided with a plurality of second via holes 520. The second via holes 520 correspond to the auxiliary electrodes 320, and the first via holes 420 correspond to the second via holes 520. In a manufacturing process, the auxiliary electrodes 320 are exposed, and the cathode layer 700 is electrically connected to the auxiliary electrodes 320 through the first via holes 420 and the second via holes 520.

In some embodiments, during a manufacturing process, the printed ink 610 floods the second pixel definition layer 500 and is leveled, and after drying, the light emitting layer 600 is filled in the first pixel openings 410. Before printing the ink 610, a plurality of hole injection layers and a plurality of hole transport layers may be formed on the anode electrodes 310.

The display panel 100 further includes a plurality of hole injection layers and a plurality of hole transport layers disposed between the light emitting layer 600 and the anode electrodes 310. The hole injection layers corresponding to two adjacent anode electrodes 310 are spaced apart and insulated from each other, and the hole transport layers corresponding to the two adjacent anode electrodes 310 are spaced apart and insulated from each other, so as to reduce transmission of holes between the two adjacent anode electrodes 310 and avoid affecting independent control of light emission.

In some embodiments, a thickness of the second pixel definition layer 500 is greater than or equal to a thickness of the anode electrodes 310. The thickness of the second pixel definition layer 500 needs to ensure that two adjacent anode electrodes 310 are insulated from each other, so as to achieve independent control of different light-emitting pixels.

In some embodiments, the second pixel definition layer 500 is in contact with surfaces of the anode electrodes 310 away from the substrate 200. The second pixel definition layer 500 surrounds a part of the surface of each of the anode electrodes 310 away from the substrate 200, so as to further strengthen insulation between two adjacent anode electrodes 310. This prevents currents between the two adjacent anode electrodes 310 from influencing each other, so as to achieve independent control of different light-emitting pixels.

In some embodiments, a surface hydrophobicity of the first pixel definition layer 400 is greater than a surface hydrophobicity of the second pixel definition layer 500. The first pixel definition layer 400 is configured to limit the flow of the printing ink 610, so the first pixel definition layer 400 needs to have higher hydrophobicity to enhance an effect of limiting the flow. The second pixel definition layer 500 is mainly configured for insulation, so the second pixel definition layer 500 needs to be hydrophilic, which is beneficial to the leveling of the ink 610. The first pixel definition material layer may be made of an organic material, such as an organic resin. Fluorine may be added to the organic resin to form a fluorine-containing organic resin photoresist, so as to improve the surface hydrophobicity. When the display panel is fabricated, a position of the ink can be defined. The fluorine-containing organic resin photoresist may be a positive type or a negative type, which is only an example and is not limited thereto. The second pixel definition layer 500 may be made of an organic material or an inorganic material, such as an organic resin or SiO₂, which is only an example and is not limited thereto.

In some embodiments, the first pixel definition layer 400 has a thickness of 1 μm to 3 μm, preferably 1 μm. The second pixel definition layer 500 has a thickness of 0.1 μm to 0.7 μm, preferably 0.5 μm.

In some embodiments, a surface contact angle of the first pixel definition layer 400 is greater than 60°, which is tested with an organic solvent, such as anisole.

In some embodiments, the anode layer 300 includes a first transparent conductive layer, a metal reflective layer disposed on the first transparent conductive layer, and a second transparent conductive layer disposed on the metal reflective layer. The first transparent conductive layer and/or the second transparent conductive layer may be made of indium tin oxide (ITO), indium zinc oxide (IZO), or the like. The metal reflective layer may be made of Al, Ag, Mg, or the like.

In some embodiments, the metal reflective layer has a thickness of 50 nm to 1000 nm. The first transparent conductive layer or/and the second transparent conductive layer have a thickness of 10 nm to 200 nm.

In some embodiments, the substrate 200 includes a base substrate, an active layer disposed on the base substrate, a first insulating layer disposed on the active layer, a gate layer disposed on the first insulating layer, a second insulating layer disposed on the gate layer, a source and drain layer disposed on the second insulating layer, and a third insulating layer disposed on the source and drain layer.

In some embodiments, the display panel 100 further includes a polarizing layer disposed on an encapsulation layer, and a flexible cover plate disposed on the polarizing layer.

In the present disclosure, the second pixel definition layer is configured to insulate two adjacent anode electrodes, so that light emission of the two adjacent light-emitting pixels can be independently controlled. An ink is printed in one first pixel opening, and an amount of the ink corresponds to at least two light-emitting pixels of a same color. Even if one printing nozzle is blocked, the amount of the ink corresponding to at least two light-emitting pixels is evenly distributed. This can reduce a relative error of an ink amount caused by a reduction of an ejected ink amount, thereby improving a printing quality and improving a display effect.

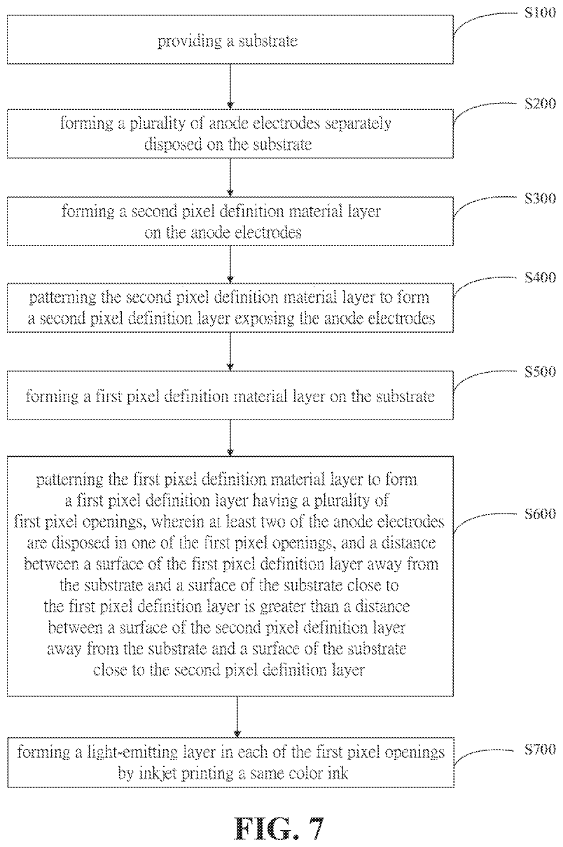

Please refer to FIG. 7, the present disclosure further provides a method for manufacturing a display panel 100. The method comprises the following steps.
S100: providing a substrate 200.
S200: forming a plurality of anode electrodes 310 separately disposed on the substrate 200.
S300: forming a second pixel definition material layer on the anode electrodes 310.
S400: patterning the second pixel definition material layer to form a second pixel definition layer 500 exposing the anode electrodes 310.
S500: forming a first pixel definition material layer on the substrate 200.
S600: patterning the first pixel definition material layer to form a first pixel definition layer 400 having a plurality of first pixel openings 410, wherein at least two of the anode electrodes 310 are disposed in one of the first pixel openings 410, and a distance between a surface of the first pixel definition layer 400 away from the substrate 200 and a surface of the substrate 200 close to the first pixel definition layer 400 is greater than a distance between a surface of the second pixel definition layer 500 away from the substrate 200 and a surface of the substrate 200 close to the second pixel definition layer 500.
S700: forming a light-emitting layer 600 in each of the first pixel openings 410 by inkjet printing a printing ink 610 of a same color.

The second pixel definition layer 500 is disposed at least between two adjacent anode electrodes 310 in each of the first pixel openings 410.

In the present disclosure, the second pixel definition layer is configured to insulate two adjacent anode electrodes, so that light emission of the two adjacent light-emitting pixels can be independently controlled. An ink is printed in one first pixel opening, and an amount of the ink corresponds to at least two light-emitting pixels of a same color. Even if one printing nozzle is blocked, the amount of the ink corresponding to at least two light-emitting pixels is evenly distributed. This can reduce a relative error of an ink amount caused by a reduction of an ejected ink amount, thereby improving a printing quality and improving a display effect.

The technical solutions of the present disclosure will now be described with reference to the specific embodiments.

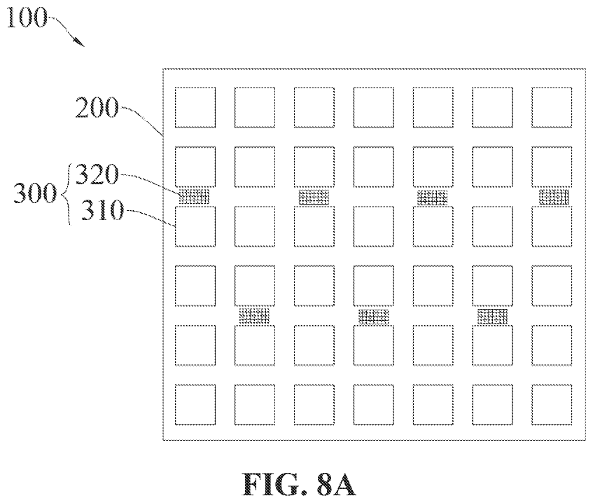

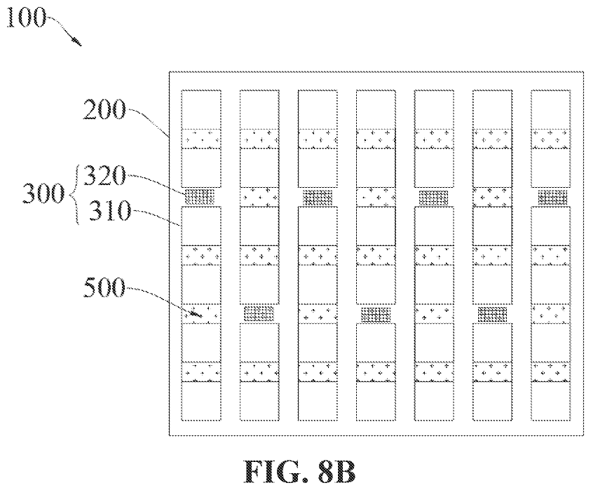

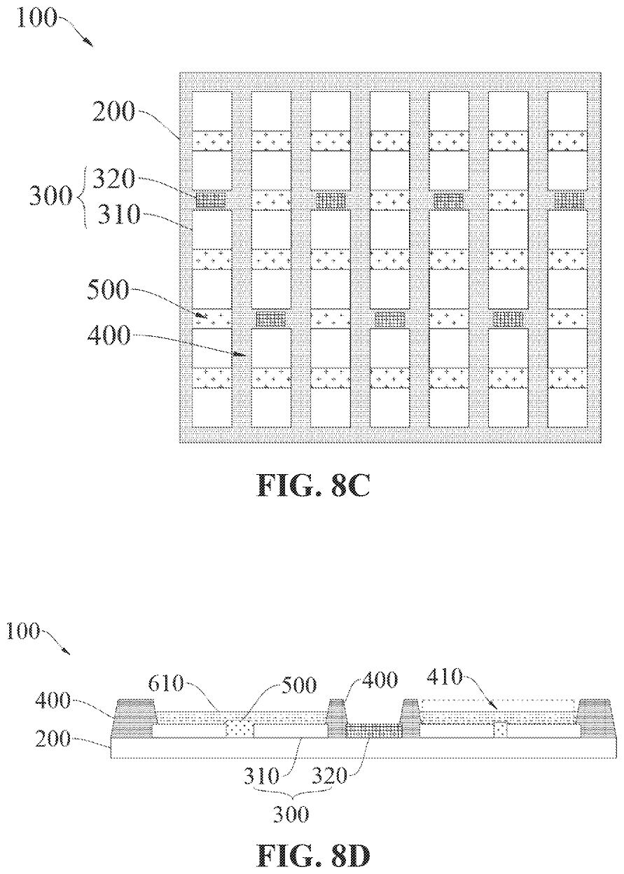

In this embodiment, the method for manufacturing the display panel 100 comprises the following steps.
S100: providing a substrate 200, please refer to FIG. 8A.

In some embodiments, the substrate 200 includes a base substrate, an active layer disposed on the base substrate, a first insulating layer disposed on the active layer, a gate layer disposed on the first insulating layer, a second insulating layer disposed on the gate layer, a source and drain layer disposed on the second insulating layer, and a third insulating layer disposed on the source and drain layer.
S200: forming a plurality of anode electrodes 310 separately disposed on the substrate 200, please refer to FIG. 8A.

In some embodiments, step S200 includes the following step.
S210: forming a metal layer on the substrate 200.

According to whether auxiliary electrodes 320 are formed, step S200 further includes one of the following steps.
S220a: patterning the metal layer to form the separately arranged anode electrodes 310.
S220b: patterning the metal layer to form the anode electrodes 310 that are separately arranged and the auxiliary electrodes 320 each arranged between two adjacent anode electrodes 310, please refer to FIG. 8A.

In some embodiments, the anode layer 300 includes a first transparent conductive layer, a metal reflective layer disposed on the first transparent conductive layer, and a second transparent conductive layer disposed on the metal reflective layer. The first transparent conductive layer and/or the second transparent conductive layer may be made of indium tin oxide (ITO), indium zinc oxide (IZO), or the like. The metal reflective layer may be made of Al, Ag, Mg, or the like.
S300: forming a second pixel definition material layer on the anode electrodes 310.

In some embodiments, the second pixel definition material layer may be made of an organic material or an inorganic material, such as an organic resin or SiO₂, which is only an example and is not limited thereto.
S400: patterning the second pixel definition material layer to form a second pixel definition layer 500 exposing the anode electrodes 310, please refer to FIG. 8B.

In some embodiments, the second pixel definition layer 500 is disposed at least between two adjacent anode electrodes 310 in each of the first pixel openings 410

In some embodiments, according to whether the auxiliary electrodes 320 are formed, the step S400 is one of the following steps.
S400a: patterning the second pixel definition material layer to form the second pixel definition layer 500 exposing the anode electrodes 310.
S400b: patterning the second pixel definition material layer to form a second pixel definition layer 500 exposing the anode electrodes 310 and the auxiliary electrodes 320, please refer to FIG. 8B.

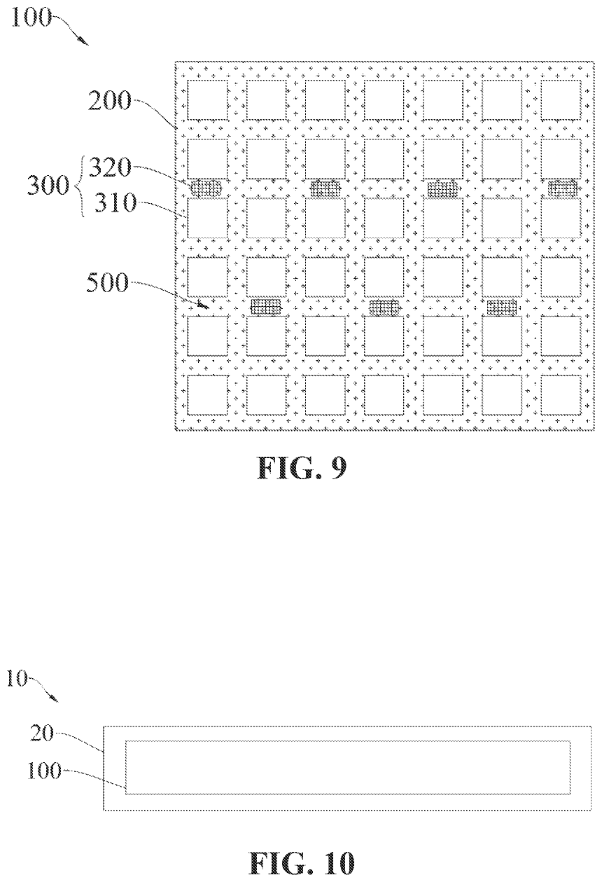

In some embodiments, according to whether the second pixel definition layer 500 is disposed on a periphery of each of the anode electrodes 310, step S400 includes one of the following steps.
S410c: patterning the second pixel definition material layer to expose the anode electrodes 310, so as to form a second pixel definition layer 500 located between at least two adjacent anode electrodes 310 in the first direction, please refer to FIG. 8B.
S410d: patterning the second pixel definition material layer to form a plurality of second pixel openings 510, so as to form a second pixel definition layer 500 located between any two adjacent anode electrodes 310, wherein one of the second pixel openings 510 exposes one of the anode electrodes 310, please refer to FIG. 9.

In some embodiments, the second pixel definition layer 500 is disposed on a periphery of each of the anode electrodes 310. The second pixel definition layer 500 is provided with a plurality of second pixel openings 510. One of the second pixel openings 510 corresponds to one of the anode electrodes 310. The first pixel definition layer 400 is disposed on the surface of the second pixel definition layer 500 away from the substrate 200. In the top view direction of the display panel 100, at least two of the second pixel openings 510 are located in one of the first pixel openings 410.

In some embodiments, step S410d is as follows.
S411d: patterning the second pixel definition material layer to form a plurality of second pixel openings 510 and a plurality of second via holes 520, so as to form a second pixel definition layer 500 located between any two adjacent anode electrodes 310, wherein one of the second pixel openings 510 exposes one of the anode electrodes 310, and one of the second via holes 520 exposes one of the auxiliary electrodes 320.

In some embodiments, please refer to FIG. 4 and FIG. 5, the second pixel definition layer 500 and the first pixel definition layer 400 are disposed between the cathode layer 700 and the auxiliary electrodes 320. The pixel definition layer is provided with a plurality of first via holes 420. The second pixel definition layer 500 is provided with a plurality of second via holes 520. The second via holes 520 correspond to the auxiliary electrodes 320, and the first via holes 420 correspond to the second via holes 520. In a manufacturing process, the auxiliary electrodes 320 are exposed, and the cathode layer 700 is electrically connected to the auxiliary electrodes 320 through the first via holes 420 and the second via holes 520.
S500: forming a first pixel definition material layer on the substrate 200.

In some embodiments, a surface hydrophobicity of the first pixel definition layer 400 is greater than a surface hydrophobicity of the second pixel definition layer 500. The first pixel definition layer 400 is configured to limit the flow of the printing ink 610, so the first pixel definition layer 400 needs to have higher hydrophobicity to enhance an effect of limiting the flow. The second pixel definition layer 500 is mainly configured for insulation, so the second pixel definition layer 500 needs to be hydrophilic, which is beneficial to the leveling of the ink 610. The first pixel definition material layer may be made of an organic material, such as an organic resin. Fluorine may be added in the organic resin to form a fluorine-containing organic resin photoresist, so as to improve the surface hydrophobicity. The fluorine-containing organic resin photoresist may be positive type or negative type, which is only an example and is not limited thereto. The second pixel definition material layer may be made of an organic material or an inorganic material, such as an organic resin or SiO₂, which is only an example and is not limited thereto.
S600: patterning the first pixel definition material layer to form a first pixel definition layer 400 having a plurality of first pixel openings 410, wherein at least two of the anode electrodes 310 are disposed in one of the first pixel openings 410, and a distance between a surface of the first pixel definition layer 400 away from the substrate 200 and a surface of the substrate 200 close to the first pixel definition layer 400 is greater than a distance between a surface of the second pixel definition layer 500 away from the substrate 200 and a surface of the substrate 200 close to the second pixel definition layer 500, please refer to FIG. 8C, FIG. 3, and FIG. 4.

In a process of manufacturing the display panel 100, the distance between the surface of the first pixel definition layer 400 away from the substrate 200 and the surface of the substrate 200 close to the first pixel definition layer 400 is greater than the distance between the surface of the second pixel definition layer 500 away from the substrate 200 and the surface of the substrate 200 close to the second pixel definition layer 500. The first pixel definition layer 400 is configured to restrict a flow of a printing ink 610. The second pixel definition layer 500 is at least configured to insulate two adjacent anode electrodes 310 in one first pixel opening 410. The first pixel definition layer 400 or the second pixel definition layer 500 may be configured to insulate two adjacent anode electrodes 310 in two adjacent first pixel openings 410 according to different patterning processes.

The light-emitting pixels in one of the first pixel openings 410 have a same light-emitting color, so an ink 610 is printed in one first pixel opening 410, and an amount of the ink 610 corresponds to at least two light-emitting pixels of a same color. Even if one printing nozzle is blocked, since the second pixel definition layer 500 does not block leveling of the ink 610, the amount of the ink 610 corresponding to at least two light-emitting pixels is evenly distributed. This can reduce a relative error of the amount of the ink 610 caused by a reduction of an ejected ink amount, thereby improving a printing quality and improving a display effect.

In some embodiments, step S600 includes the following step.
S610: patterning the first pixel definition material layer to form a first pixel definition layer 400 having a plurality of first pixel openings 410 and a plurality of first via holes 420, wherein at least two of the anode electrodes 310 are disposed in one of the first pixel openings 410, each of the first via holes 420 corresponds to one of the auxiliary electrodes 320, and a distance between a surface of the first pixel definition layer 400 away from the substrate 200 and a surface of the substrate 200 close to the first pixel definition layer 400 is greater than a distance between a surface of the second pixel definition layer 500 away from the substrate 200 and a surface of the substrate 200 close to the second pixel definition layer 500, please refer to FIG. 8C, FIG. 3, and FIG. 4.

In some embodiments, only the first pixel definition layer 400 is disposed between the cathode layer 700 and the auxiliary electrodes 320. The first pixel definition layer 400 is provided with a plurality of first via holes 420. The first via holes 420 correspond to the auxiliary electrodes 320. In a manufacturing process, the auxiliary electrodes 320 are exposed, and the cathode layer 700 is electrically connected to the auxiliary electrodes 320 through the first via holes 420.

In some embodiments, the second pixel definition layer 500 and the first pixel definition layer 400 are disposed between the cathode layer 700 and the auxiliary electrodes 320. The pixel definition layer is provided with a plurality of first via holes 420. The second pixel definition layer 500 is provided with a plurality of second via holes 520. The second via holes 520 correspond to the auxiliary electrodes 320, and the first via holes 420 correspond to the second via holes 520. In a manufacturing process, the auxiliary electrodes 320 are exposed, and the cathode layer 700 is electrically connected to the auxiliary electrodes 320 through the first via holes 420 and the second via holes 520.
S700: forming a light-emitting layer 600 in each of the first pixel openings 410 by inkjet printing a printing ink 610 of a same color, please refer to FIG. 8D.

In some embodiments, step S700 includes the following steps.
S710: forming a plurality of hole injection layers and a plurality of hole transport layers in the first pixel openings 410.

In some embodiments, during a manufacturing process, the printed ink 610 floods the second pixel definition layer 500 and is leveled, and after drying, the light emitting layer 600 is filled in the first pixel openings 410. Before printing the ink 610, a plurality of hole injection layers and a plurality of hole transport layers may be formed on the anode electrodes 310.

The display panel 100 further includes a plurality of hole injection layers and a plurality of hole transport layers disposed between the light emitting layer 600 and the anode electrodes 310. The hole injection layers corresponding to two adjacent anode electrodes 310 are spaced apart and insulated from each other, and the hole transport layers corresponding to the two adjacent anode electrodes 310 are spaced apart and insulated from each other, so as to reduce transmission of holes between the two adjacent anode electrodes 310 and avoid affecting independent control of light emission.
S720: forming one light-emitting layer 600 in each of the first pixel openings 410 by inkjet printing the printing ink 610 of the same color.

The light-emitting pixels in one of the first pixel openings 410 have a same light-emitting color, so an ink 610 is printed in one first pixel opening 410, and an amount of the ink 610 corresponds to at least two light-emitting pixels of a same color. Even if one printing nozzle is blocked, since the second pixel definition layer 500 does not block leveling of the ink 610, the amount of the ink 610 corresponding to at least two light-emitting pixels is evenly distributed. This can reduce a relative error of the amount of the ink 610 caused by a reduction of an ejected ink amount, thereby improving a printing quality and improving a display effect.

In some embodiments, step S720 includes the following steps.
S721: inkjet printing the printing ink 610 of the same color in each of the first pixel openings 410.
S722: drying the printing ink 610 to form the light-emitting layer 600.

In some embodiments, step S722 may be performed after the following step S730 for overall drying.
S730: forming the hole injection layers and the hole transport layers in the first pixel openings 410.
S740: forming a cathode layer 700 on the substrate 200.

In some embodiments, the cathode layer 700 is electrically connected to the auxiliary electrodes 320 through the first via holes 420, or through the first via holes 420 and the second via holes 520.

In some embodiments, for a top emission display panel 100, a cathode layer 70 is generally made of a metal film with high activity, such as an Mg/Ag translucent film. When a transparent cathode film has a small thickness, the transparent cathode film has a high impedance and a low conductivity. Electrode input terminals with different distances produce different voltage drops.

In some embodiments, for a specific structure of the display panel 100, reference may be made to the display panel 100 of any of the above embodiments and the accompanying drawings, which will not be described in detail herein.

In the present disclosure, the second pixel definition layer is configured to insulate two adjacent anode electrodes, so that light emission of the two adjacent light-emitting pixels can be independently controlled. An ink is printed in one first pixel opening, and an amount of the ink corresponds to at least two light-emitting pixels of a same color. Even if one printing nozzle is blocked, the amount of the ink corresponding to at least two light-emitting pixels is evenly distributed. This can reduce a relative error of an ink amount caused by a reduction of an ejected ink amount, thereby improving a printing quality and improving a display effect.

Please refer to FIG. 10, the present disclosure further provides a display device 10, which includes any display panel 100 as described above and a device body 20. The device body 20 and the display panel 100 are combined into one body.

For a specific structure of the display panel 100, reference may be made to the display panel 100 of any of the above embodiments and FIG. 1 to FIG. 6, which will not be described in detail herein.

In this embodiment, the device body 20 may comprise a middle frame, a sealant, and the like. The display device 10 may be a large-sized display terminal, which is not limited herein.

The present disclosure provides a display panel, a method for manufacturing the same, and a display device. The display panel comprises a substrate, an anode layer comprising a plurality of anode electrodes, a first pixel definition layer, and a second pixel definition layer. The first pixel definition layer is provided with a plurality of first pixel openings. At least two of the anode electrodes are disposed in one of the first pixel openings. The second pixel definition layer is disposed at least between two adjacent anode electrodes in each of the first pixel openings. Light-emitting pixels in one of the first pixel openings have a same light-emitting color. A distance between a surface of the first pixel definition layer away from the substrate and a surface of the substrate close to the first pixel definition layer is greater than a distance between a surface of the second pixel definition layer away from the substrate and a surface of the substrate close to the second pixel definition layer. In the present disclosure, an ink is printed in one first pixel opening, and an amount of the ink corresponds to at least two light-emitting pixels of a same color. Therefore, the amount of the ink corresponding to at least two light-emitting pixels is evenly distributed, thereby reducing a relative error of an ink amount.

It should be understood that those skilled in the art may make equivalent replacements or changes based on the technical solutions and inventive concepts of the present application, and all such changes or replacements shall fall within the scope of the claims of the present application.

1. A display panel, comprising:
a substrate;
an anode layer disposed on the substrate and comprising a plurality of anode electrodes that are separately arranged;
a first pixel definition layer disposed on the substrate and provided with a plurality of first pixel openings, wherein in a top view direction of the display panel, at least two of the anode electrodes are disposed in one of the first pixel openings; and
a second pixel definition layer disposed on the substrate and disposed at least between two adjacent anode electrodes in each of the first pixel openings;
wherein each of the first pixel openings has at least two light-emitting pixels with a same light-emitting color, each of the light-emitting pixels corresponds to one of the anode electrodes, and a distance between a surface of the first pixel definition layer away from the substrate and a surface of the substrate close to the first pixel definition layer is greater than a distance between a surface of the second pixel definition layer away from the substrate and a surface of the substrate close to the second pixel definition layer.

2. The display panel according to claim 1, wherein the second pixel definition layer is disposed on a periphery of each of the anode electrodes, the second pixel definition layer is provided with a plurality of second pixel openings, one of the second pixel openings corresponds to one of the anode electrodes, the first pixel definition layer is disposed on the surface of the second pixel definition layer away from the substrate, and in the top view direction of the display panel, at least two of the second pixel openings are located in one of the first pixel openings.

3. The display panel according to claim 1, wherein in the top view direction of the display panel, in each of the first pixel openings, a column of the anode electrodes arranged in a first direction, the light-emitting pixels in a same column of the first pixel openings in the first direction have a same light-emitting color, the light-emitting pixels in two adjacent columns of the first pixel openings in a second direction have different light-emitting colors, and the first direction is perpendicular to the second direction.

4. The display panel according to claim 3, wherein the anode layer further comprises a plurality of auxiliary electrodes disposed in a same layer as the anode electrodes and insulated from the anode electrodes, and in the first direction, each of the auxiliary electrodes is disposed between two adjacent first pixel openings.

5. The display panel according to claim 4, wherein two adjacent first pixel openings in the first direction have different numbers of the anode electrodes, and two adjacent first pixel openings in the second direction are not flush with each other.

6. The display panel according to claim 4, wherein in a direction from an edge of the display panel to a center of the display panel, a number density of the auxiliary electrodes gradually increases.

7. The display panel according to claim 4, further comprising:
a plurality of light-emitting layers disposed on the anode electrodes; and
a cathode layer disposed on the light-emitting layers, wherein the cathode layer is electrically connected to the auxiliary electrodes through via holes.

8. The display panel according to claim 1, wherein a thickness of the second pixel definition layer is greater than or equal to a thickness of the anode electrodes.

9. The display panel according to claim 8, wherein the second pixel definition layer is in contact with surfaces of the anode electrodes away from the substrate.

10. The display panel according to claim 1, wherein a surface hydrophobicity of the first pixel definition layer is greater than a surface hydrophobicity of the second pixel definition layer.

11. A method for manufacturing a display panel, comprising:
providing a substrate;
forming a plurality of anode electrodes separately disposed on the substrate;
forming a second pixel definition material layer on the anode electrodes;
patterning the second pixel definition material layer to form a second pixel definition layer exposing the anode electrodes;
forming a first pixel definition material layer on the substrate;
patterning the first pixel definition material layer to form a first pixel definition layer having a plurality of first pixel openings, wherein at least two of the anode electrodes are disposed in one of the first pixel openings, the second pixel definition layer is disposed at least between two adjacent anode electrodes in each of the first pixel openings, and a distance between a surface of the first pixel definition layer away from the substrate and a surface of the substrate close to the first pixel definition layer is greater than a distance between a surface of the second pixel definition layer away from the substrate and a surface of the substrate close to the second pixel definition layer; and
forming a light-emitting layer in each of the first pixel openings by inkjet printing a same color ink.

12. The method for manufacturing the display panel according to claim 11, wherein
the second pixel definition layer is provided with a plurality of second pixel openings, one of the second pixel openings exposes one of the anode electrodes; and
the first pixel definition material layer is formed on the second pixel definition layer.

13. The method for manufacturing the display panel according to claim 11, comprising:
forming a plurality of auxiliary electrodes on the substrate, wherein each of the auxiliary electrodes is disposed between two adjacent anode electrodes;
patterning the second pixel definition material layer to expose the auxiliary electrodes;
patterning the first pixel definition material layer to form a plurality of first via holes exposing the auxiliary electrodes; and
forming a cathode layer on the light-emitting layers and the auxiliary electrodes.

14. A display device, comprising a display panel and a device body that are combined into one body, wherein the display panel comprises:
a substrate;
an anode layer disposed on the substrate and comprising a plurality of anode electrodes that are separately arranged;
a first pixel definition layer disposed on the substrate and provided with a plurality of first pixel openings, wherein in a top view direction of the display panel, at least two of the anode electrodes are disposed in one of the first pixel openings; and
a second pixel definition layer disposed on the substrate and disposed at least between two adjacent anode electrodes in each of the first pixel openings;
wherein each of the first pixel openings has at least two light-emitting pixels with a same light-emitting color, each of the light-emitting pixels corresponds to one of the anode electrodes, and a distance between a surface of the first pixel definition layer away from the substrate and a surface of the substrate close to the first pixel definition layer is greater than a distance between a surface of the second pixel definition layer away from the substrate and a surface of the substrate close to the second pixel definition layer.

15. The display device according to claim 14, wherein the second pixel definition layer is disposed on a periphery of each of the anode electrodes, the second pixel definition layer is provided with a plurality of second pixel openings, one of the second pixel openings corresponds to one of the anode electrodes, the first pixel definition layer is disposed on the surface of the second pixel definition layer away from the substrate, and in the top view direction of the display panel, at least two of the second pixel openings are located in one of the first pixel openings.

16. The display device according to claim 14, wherein in the top view direction of the display panel, in each of the first pixel openings, a column of the anode electrodes arranged in a first direction, the light-emitting pixels in a same column of the first pixel openings in the first direction have a same light-emitting color, the light-emitting pixels in two adjacent columns of the first pixel openings in a second direction have different light-emitting colors, and the first direction is perpendicular to the second direction.

17. The display device according to claim 16, wherein the anode layer further comprises a plurality of auxiliary electrodes disposed in a same layer as the anode electrodes and insulated from the anode electrodes, and in the first direction, each of the auxiliary electrodes is disposed between two adjacent first pixel openings.

18. The display device according to claim 17, wherein two adjacent first pixel openings in the first direction have different numbers of the anode electrodes, and two adjacent first pixel openings in the second direction are not flush with each other.

19. The display device according to claim 14, wherein a thickness of the second pixel definition layer is greater than or equal to a thickness of the anode electrodes.

20. The display device according to claim 14, wherein a surface hydrophobicity of the first pixel definition layer is greater than a surface hydrophobicity of the second pixel definition layer.
